(19) United States
(12) Patent Application Publication
(10) Pub. No.: US 2018/0047569 A1
(43) Pub. Date: Feb. 15, 2018

(54) METHOD OF SELECTIVE EPITAXY

(71) Applicant: Applied Materials, Inc., Santa Clara, CA (US)

(72) Inventors: Yi-Chiau HUANG, Fremont, CA (US); Hua CHUNG, San Jose, CA (US); Abhishek DUBE, Fremont, CA (US)

(21) Appl. No.: 15/795,070

(22) Filed: Oct. 26, 2017

Related U.S. Application Data
(62) Division of application No. 15/156,870, filed on May 17, 2016.
(60) Provisional application No. 62/192,801, filed on Jul. 15, 2015.

(51) Int. Cl. H01L 21/02; H01L 21/311

(52) U.S. Cl. CPC H01L 21/02532; H01L 21/31105; H01L 21/02642; H01L 21/02639; H01L 21/0262; H01L 21/02164; H01L 21/02576; H01L 21/02433; H01L 21/02381; H01L 21/0217; H01L 21/02579

(57) ABSTRACT

Embodiments of the present disclosure generally relate to methods for trench filling of high quality epitaxial silicon-containing material without losing selectivity of growth to dielectrics such as silicon oxides and silicon nitrides. The methods include epitaxially growing a silicon-containing material within a trench formed in a dielectric layer by exposing the trench to a gas mixture comprising a halogenated silicon compound and a halogenated germanium compound. In one embodiment, the halogenated silicon compound includes chlorinated silane and halogenated germanium compound includes chlorinated germane.

### CROSS-REFERENCE TO RELATED APPLICATIONS

This application is a divisional of U.S. patent application Ser. No. 15/156,870, filed May 17, 2016, which claims priority to U.S. provisional patent application Ser. No. 62/192,801, filed Jul. 15, 2015, both applications are hereby incorporated by reference.

### BACKGROUND

### Field

Embodiments of the disclosure generally relate to the field of semiconductor manufacturing processes and devices, more particularly, to methods of depositing silicon-containing films for forming semiconductor devices.

### Description of the Related Art

Semiconductor industry is in the era of transitioning from 2D transistors, which are often planar, to 3D transistors using a three-dimensional gate structure. In 3D gate structures, the channel, source and drain are raised out of the substrate and the gate is then wrapped around the channel on three sides. The goal is to constrain the current to only the raised channel, and abolish any path through which electrons may leak. One such type of 3D transistors is known as FinFET (Fin field-effect transistor), in which the channel connecting the source and drain is a thin “fin” jutting out of the substrate. This results in the current being constrained to the channel, thereby preventing electrons from leaking.

A typical FinFET structure may have a dielectric layer stack formed on a bulk silicon substrate. The dielectric layer stack may include a silicon oxide and a silicon nitride. The dielectric layer stack may be etched to form trenches for shallow trench isolation structure needed for source/drain regions. The trenches are then filled with silicon, germanium, or silicon germanium using a selective epitaxial process. During the trench filling, it has been observed that the epitaxial material, for example silicon germanium, is more selective to silicon oxide areas than to silicon nitride areas on the sidewall of the trenches. This phenomenon makes it very challenging for epitaxial growth in narrow trenches with silicon oxide sidewall, while having the same growth selective to silicon nitride areas on the sidewall. If the epitaxial material is starting on a Si (100) surface, such selectivity of growth also causes the epitaxial material to form facets within the trenches oriented along the <110> directions. The surface morphology of the epitaxial material is suffered due to the formation of the facets, resulting in a higher concentration of the defects and poor electrical properties.

Therefore, there is a need for an improved selective epitaxial process that can grow silicon germanium in trenches without losing selectivity of growth to dielectrics such as silicon oxide and silicon nitride.

### SUMMARY

Embodiments of the present disclosure generally relate to methods for selective epitaxial growth of a silicon-containing material, such as a silicon germanium, in a trench isolation structure on a substrate or layers including silicon oxide, silicon nitride, or a combination thereof. In one embodiment, the method includes epitaxially growing a silicon-containing material within a trench formed in a dielectric layer by exposing the trench to a gas mixture comprising a halogenated silicon compound and a halogenated germanium compound. In one example, the halogenated silicon compound includes chlorinated silane and the halogenated germanium compound includes chlorinated germane.

In another embodiment, the method includes forming a dielectric layer on a silicon substrate, forming a trench in the dielectric layer to expose a portion of the silicon substrate through the trench, and epitaxially growing a silicon-containing material in the trench by exposing the trench to a gas mixture comprising a halogenated silicon compound and a halogenated germanium compound.

In yet another embodiment, the method includes epitaxially growing a silicon germanium on a dielectric layer formed over a substrate by exposing a region of the dielectric layer to a gas mixture comprising a chlorinated germane gas and a silicon-containing gas comprising silane (SiH₄), disilane (Si₂H₆), trisilane (Si₃H₈), or tetrasilane (Si₄H₁₀), wherein the region comprises a silicon oxide and a silicon nitride.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flow chart illustrating an exemplary method for manufacturing an integrated circuit according to embodiments of the disclosure.

FIGS. 2A to 2E illustrate perspective views of a simplified, conceptual integrated circuit during certain stages of fabrication according to the flow chart of FIG. 1.

To facilitate understanding, identical reference numerals have been used, where possible, to designate identical elements that are common to the figures. It is contemplated that elements disclosed in one embodiment may be beneficially utilized in other embodiments without specific recitation.

### DETAILED DESCRIPTION

Embodiments of the present disclosure provide methods for manufacturing semiconductor devices such as transistors used for amplifying or switching electronic signals. For example, the disclosed methods may be utilized in the manufacture of CMOS (Complementary Metal-Oxide-Semiconductor) transistors. While embodiments described in this disclosure use a general term “integrated circuit” as an example, it should be understood that these embodiments are equally applicable to any integrated circuit technologies such as bipolar, N-type or P-type metal oxide semiconductor (NMOS or PMOS), or CMOS etc. Particularly, embodiments of the present disclosure can benefit processes of fabricating NMOS/PMOS inverters or gates, CMOS inverters or gates, any integral circuit devices incorporating a gate structure, or any integral circuit devices having transistors (2D or 3D) or multiple gate structures.

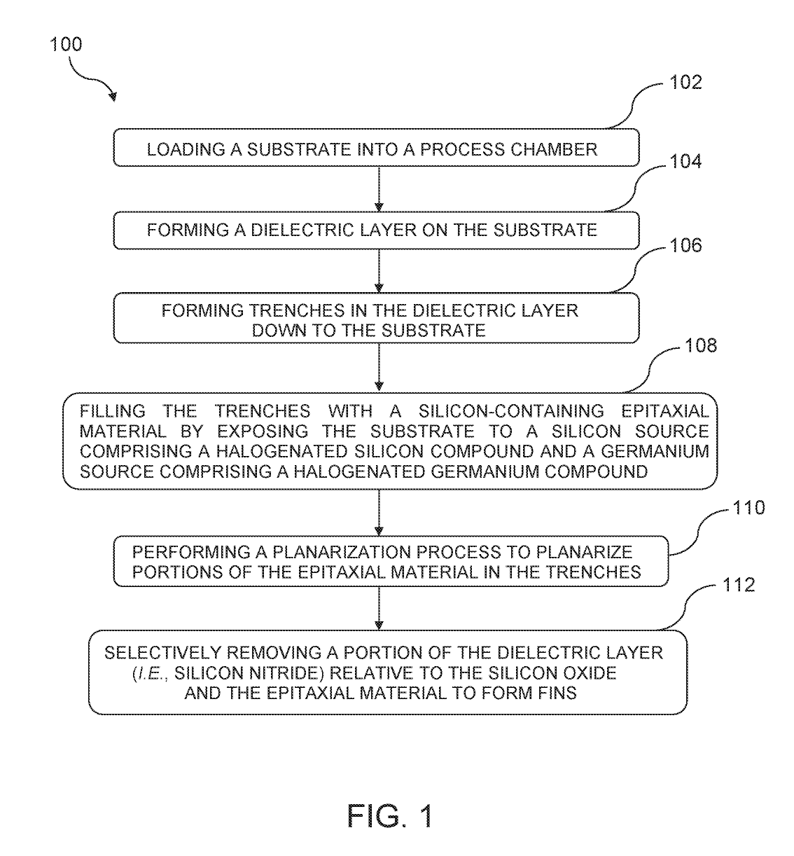

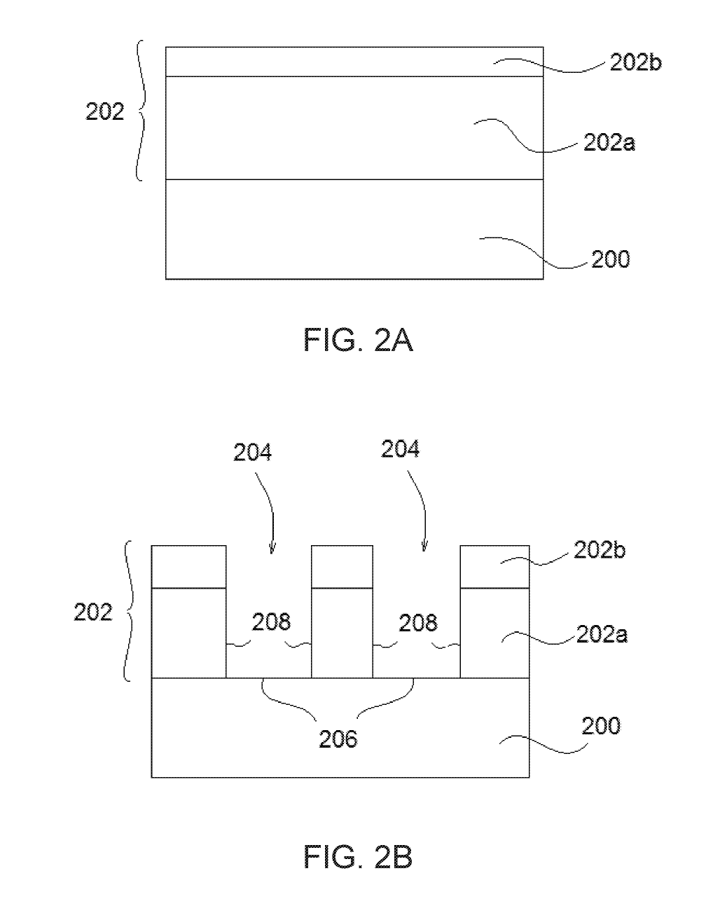

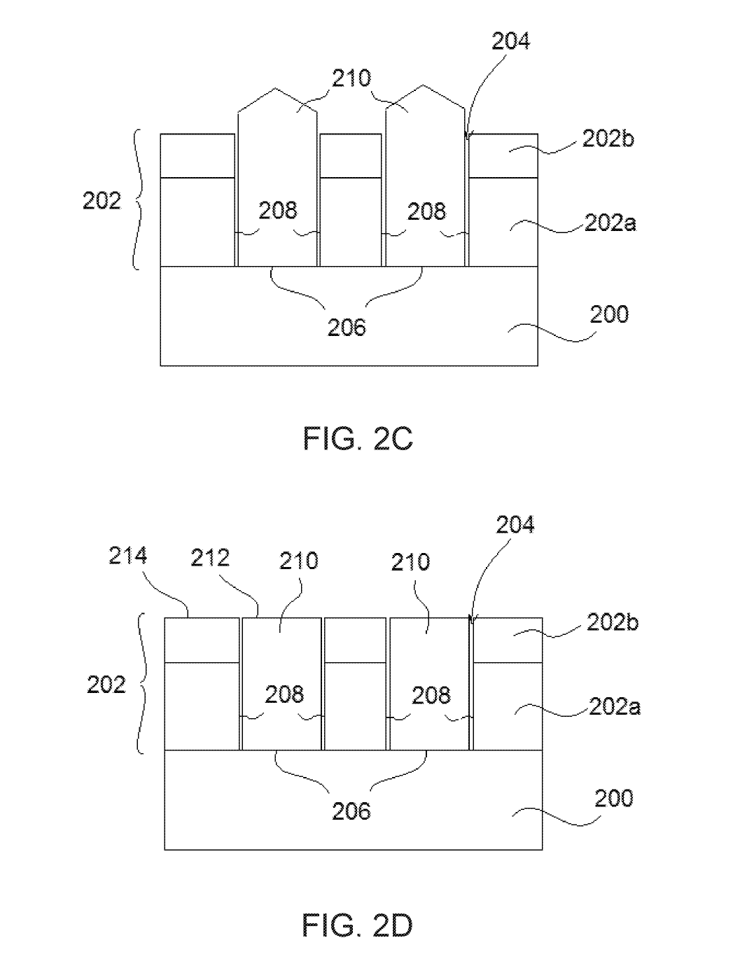

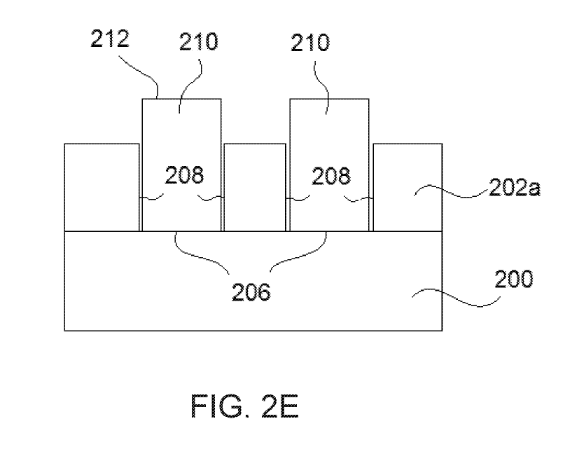

FIG. 1 depicts a flow chart illustrating an exemplary method 100 for manufacturing an integrated circuit according to embodiments of the disclosure. FIG. 1 is illustratively described with reference to FIGS. 2A-2E, which shows perspective views of a simplified, conceptual integrated circuit during certain stages of fabrication according to the flow chart of FIG. 1. Those skilled in the art will recognize that the structures FIGS. 2A-2E, while generally drawn to illustrate approximate relative sizes or dimensions for ease of understanding, are not drawn to scale. Those skilled in the art will further recognize that the full process for forming a transistor circuit and the associated structures are not illustrated in the drawings or described herein. Instead, for simplicity and clarity, only so much of a process for forming a transistor circuit and the associated structures as is unique to the present disclosure or necessary for an understanding of the present disclosure is depicted and described. In addition, although various steps are illustrated in the drawings and described herein, no limitation regarding the order of such steps or the presence or absence of intervening steps is implied. Steps depicted or described as sequential are, unless explicitly specified, merely done so for purposes of explanation without precluding the possibility that the respective steps are actually performed in concurrent or overlapping manner, at least partially if not entirely.

The method 100 begins at block 102 by loading a substrate 200 into a process chamber. The process chamber may be any suitable thermal process chamber or plasma enhanced thermal process chamber. The term “substrate” used herein is intended to broadly cover any object that can be processed in a process chamber. For example, the substrate 200 may be any substrate capable of having material deposited thereon, such as a silicon substrate, for example silicon (doped or undoped), crystalline silicon (e.g., Si<100> or Si<111>), silicon oxide, strained silicon, doped or undoped polysilicon, or the like, germanium, a III-V compound substrate, a silicon germanium (SiGe) substrate, a silicon germanium carbide (SiGeC) substrate, a silicon germanium oxide (SiGeO) substrate, a silicon germanium oxynitride (SiGeON) substrate, a silicon carbide (SiC) substrate, a silicon carbonitride (SiCN) substrate, a silicon carbonoxide (SiCO), an epi substrate, a silicon-on-insulator (SOI) substrate, a carbon doped oxide, a silicon nitride, a display substrate such as a liquid crystal display (LCD), a plasma display, an electro luminescence (EL) lamp display, a solar array, solar panel, a light emitting diode (LED) substrate, a patterned or non-patterned semiconductor wafer, glass, sapphire, or any other materials such as metals, metal alloys, and other conductive materials. The substrate may be a planar substrate or a patterned substrate. Patterned substrates are substrates that include electronic features formed into or onto a processing surface of the substrate. In either case, the substrate may contain monocrystalline surfaces and/or one secondary surface that is non-monocrystalline, such as polycrystalline or amorphous surfaces. The substrate may include multiple layers, or include, for example, partially fabricated devices such as transistors, flash memory devices, and the like. In one embodiment, the substrate is a monocrystalline silicon.

At box 104, a dielectric layer 202 is formed on the substrate 200, as shown in FIG. 2A. The dielectric layer 202 may be a single layer including an oxide, a nitride, or other suitable dielectric layer, or may be a layer stack including an oxide, a nitride, and other suitable dielectric layer. Examples of oxides may include, but are not limited to silicon dioxide (SiO₂), aluminum oxide (Al₂O₃), carbon doped silicon oxide, or silicon germanium oxides. Example of nitrides may include silicon nitride or silicon oxynitride. Other suitable dielectric material may include, but is not limited to titanium aluminum alloy, tantalum aluminum alloy, titanium nitride, titanium silicon nitride, titanium aluminum nitride, tantalum nitride, tantalum silicon nitride, hafnium nitride, hafnium silicon nitride, hafnium dioxide-alumina alloy, aluminum nitride, or a combination thereof. In one embodiment as shown, the dielectric layer 202 is a layer stack including a silicon oxide 202a and a silicon nitride 202b. The silicon nitride 202b may be deposited on the silicon oxide 202a as shown, or vice versa.

At box 106, trenches 204 are formed in the dielectric layer 202 down to the substrate 200, as shown in FIG. 2B. Each trench 204 has sidewalls and a bottom portion, and may be about 20 nm to 30 nm in width. The trenches 204 may be high in aspect ratio, e.g., 1:1 (depth to width) or greater, for example about 2:1 to about 10:1, or greater, such as 20:1. The trenches 204 may be formed by a selective etch process using any suitable wet etchants or dry etchants, depending upon the application and the dielectric material to be removed. In the embodiment as shown, the trenches 204 are formed by anisotropically removing portions of the silicon oxide 202a and the silicon nitride 202b to expose the underlying substrate 200. Once the trenches 204 are formed, a portion of the top surface 206 of the substrate 200 is exposed, and the trench sidewall 208 will reveal silicon oxide regions (e.g., silicon oxide 202a) and silicon nitride regions (e.g., silicon nitride 202b).

At box 108, the trenches 204 are filled with a silicon-containing epitaxial material 210, as shown in FIG. 2C. The silicon-containing epitaxial material is epitaxially grown in the trenches 204. The epitaxial growth may start on a Si (100) surface of the substrate 200 and fill the trenches 204. The epitaxial growth of the silicon-containing material may be initiated by exposing the substrate 200 to one or more processing reagents introduced into the process chamber. The processing reagents may be introduced into the process chamber concurrently or sequentially in the form of a gas mixture or separated gas mixtures. The processing reagents may include one or more deposition gases. In cases where the silicon-containing epitaxial material is desired, the deposition gas may contain a silicon source comprising a halogenated silicon compound. If a silicon germanium epitaxial material is desired, the deposition gas may contain a silicon source comprising a halogenated silicon compound and a germanium source comprising a halogenated germanium compound. In most cases, the epitaxial growth is performed without the use of etchant gases such as Cl₂ and HCl. In some cases, however, the epitaxial growth is performed with the use of etchant gases such as Cl₂ and HCl to help shaping of the material layer. In some embodiments, the processing reagents may include at least one dopant gas. It is contemplated that other elements, such as metals, halogens or hydrogen may be incorporated within a silicon-containing or germanium-containing epitaxial layer, usually in part per million (ppm) concentrations.

Dopant gas provides the deposited epitaxial layer with desired conductive characteristic and various electric characteristics, such as directional electron flow in a controlled and desired pathway required by the electronic device. Depending upon the application, a p-type dopant gas, such as a boron-containing dopant, or an n-type dopant gas, such as a phosphorous-containing dopant, may be introduced into the process chamber along with the gas mixture of the deposition gases. Phosphorous-containing dopants may include phosphine (PH₃). Boron-containing dopants may include boranes and organoboranes. Boranes include borane, diborane (B₂H₆), triborane, tetraborane and pentaborane, while alkylboranes include compounds with the empirical formula RₓBH₍₃₋ₓ₎, where R=methyl, ethyl, propyl or butyl and x=1, 2 or 3. Alkylboranes include trimethylborane ((CH₃)₃B), dimethylborane ((CH₃)₂BH), triethylborane ((CH₃CH₂)₃B) and diethylborane ((CH₃CH₂)₂BH). Dopants may also include arsine (AsH₃) and alkylphosphines, such as with the empirical formula RₓPH₍₃₋ₓ₎, where R=methyl, ethyl, propyl or butyl and x=1, 2 or 3. Alkylphosphines include trimethylphosphine ((CH₃)₃P), dimethylphosphine ((CH₃)₂PH), triethylphosphine ((CH₃CH₂)₃P) and diethylphosphine ((CH₃CH₂)₂PH). Aluminum and gallium dopant sources may include alkylated and/or halogenated derivates, such as described with the empirical formula RₓMX₍₃₋ₓ₎, where M=Al or Ga, R=methyl, ethyl, propyl or butyl, X=Cl or F and x=0, 1, 2 or 3. Examples of aluminum and gallium dopant sources include trimethylaluminum (Me₃Al), triethylaluminum (Et₃Al), dimethylaluminumchloride (Me₂AlCl), aluminum chloride (AlCl₃), trimethylgallium (Me₃Ga), triethylgallium (Et₃Ga), dimethylgalliumchloride (Me₂GaCl) and gallium chloride (GaCl₃).

In one exemplary embodiment, the silicon-containing epitaxial material 210 is silicon germanium (SiGe). In such a case, the deposition gas may include a silicon source and a germanium source. It has been surprisingly observed by the present inventors that epitaxial growth of SiGe in the trenches can be achieved without losing selectivity of growth to dielectrics (e.g., silicon oxide regions and silicon nitride regions appeared on the trench sidewall 208) using chlorinated silane gas as a silicon source and chlorinated germane gas as a germanium source. Exemplary chlorinated silane gases may include, but are not limited to silicon tetrachloride (SiCl₄), monochlorosilane (SiH₃Cl), dichlorosilane (Si₂H₂Cl₂), trichlorosilane (SiHCl₃), hexachlorodisilane (Si₂Cl₆), octachlorotrisilane (Si₃Cl₈), or a combination of two or more thereof. Exemplary chlorinated germane gases may include, but are not limited to germanium tetrachloride (GeCl₄), chlorogermane (GeH₃Cl), dichlorogermane (GeH₂Cl₂), trichlorogermane (GeHCl₃), hexachlorodigermane (Ge₂Cl₆), octachlorotrigermane (Ge₃Cl₈), or a combination of two or more thereof.

In some embodiments, epitaxial growth of silicon germanium may be achieved using a silicon source comprising a brominated silicon compound and a germanium source comprising a brominated germanium compound. Exemplary brominated silicon compound may be brominated silane such as SiBr₄, HSiBr₃, H₂SiBr₂, H₃SiBr, or a combination of two or more thereof.

In some embodiments, epitaxial growth of silicon germanium may be achieved using chlorinated silane gas and brominated silane gas as described herein as a silicon source, and using chlorinated germane gas and brominated germane gas as described herein as a germanium source.

In one embodiment, which can be combined with other embodiments described herein, the one or more deposition gases may flow simultaneously or concurrently (i.e., co-flow mode) with any suitable silicon-containing gas and/or any suitable germanium-containing gas during the epitaxial process. Suitable silicon-containing gases may include one or more of silanes, halogenated silanes or organosilanes. Silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀), or other higher order silane such as polychlorosilane. Halogenated silanes may include compounds with the empirical formula X′_{y}SiₓH_{(2x+2-y)}, where X′=F, Cl, Br or I, such as hexachlorodisilane (Si₂Cl₆), tetrachlorosilane (SiCl₄), dichlorosilane (Cl₂SiH₂) and trichlorosilane (Cl₃SiH). Organosilanes may include compounds with the empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂). Suitable germanium-containing gases may include, but are not limited to germane (GeH₄), digermane (Ge₂H₆), trigermane (Ge₃H₈), or a combination of two or more thereof.

In some embodiments, epitaxial growth of silicon germanium may be achieved using chlorinated germane gas, germanium-containing gas and silicon-containing gas as described herein. In one example, the chlorinated germane gas is germanium tetrachloride (GeCl₄) and/or dichlorogermane (GeH₂Cl₂), germanium-containing gas is germane (GeH₄), and silicon-containing gas is silane, trichlorosilane (TCS), dichlorosilane (DCS), or a combination of two or more thereof.

In some embodiments, epitaxial growth of silicon germanium may be achieved using chlorinated germane gas and silicon-containing gas as described herein. In one example, the chlorinated germane gas is germanium tetrachloride (GeCl₄) and/or dichlorogermane (GeH₂Cl₂), and silicon-containing gas is silane, trichlorosilane (TCS), dichlorosilane (DCS), or a combination of two or more thereof.

In some embodiments, epitaxial growth of silicon germanium may be achieved using brominated germane gas, germanium-containing gas, and silicon-containing gas as described herein.

In some embodiments, epitaxial growth of silicon germanium may be achieved using brominated germane gas and silicon-containing gas as described herein.

In any of the embodiments described herein, a carrier gas may be flowed along with the one or more deposition gases. The carrier gas may be selected based on the deposition gas(es) used and/or the process temperature during the epitaxial process. Suitable carrier gases include nitrogen, hydrogen, argon, helium, or other gases which are inert with respect to the epitaxial process. Nitrogen may be utilized as a carrier gas in embodiments featuring low temperature (e.g., <850° C.) processes.

In one embodiment, which can be combined with other embodiments described herein, the one or more deposition gases may flow in combination with a process controlling gas such as Cl₂, H₂, HCl, HBr, or H, or a combination of two or more thereof to help tune the shape (i.e., faceting) or surface morphology of the epitaxial material. In such a case, the one or more deposition gases may be continuously flowed into the process chamber with the process controlling gas provided at predetermined interval(s). In some embodiments, the one or more deposition gases and the process controlling gas may be separately flowed into the process chamber during epitaxial process.

In one exemplary embodiment where a SiGe epitaxial material is desired, the processing reagents may comprise a silicon source comprising dichlorosilane (DCS) and a germanium source comprising germanium tetrachloride (GeCl₄). For a 200 mm or 300 mm substrate, DCS may be provided into the process chamber at a flow rate ranging from about 30 sccm to about 80 sccm, such as about 45 sccm to about 65 sccm, for example about 50 sccm. GeCl₄ may be provided into the process chamber at a flow rate ranging from about 30 sccm to about 80 sccm, such as about 45 sccm to about 65 sccm, for example about 50 sccm. The carrier gas may have a flow rate from about 0.8 SLM (standard liters per minute) to about 27 SLM, such as from about 1.8 SLM to about 18 SLM. A dopant gas (if used) may be provided into the process chamber at a flow rate ranging from about 0.1 sccm to about 600 sccm, such as from about 0.3 sccm to about 15 sccm, for example, about 1 sccm to about 10 sccm. The total flow may be about 2 SLM (standard liters per minute) to about 30 SLM, for example about 5 SLM to about 20 SLM, for a 200 mm or 300 mm substrate. The epitaxial process may be a low temperature process (e.g., below 650° C.). In one exemplary example, the epitaxial process is performed at 800° C. or below, for example about 750° C. or below, for example about 500° C. to about 750° C., such as about 550° C. to about 650° C., for example about 600° C., and a chamber pressure of about 5 Torr to about 760 Torr, such as about 20 Torr to about 100 Torr, for example about 40 Torr. It is contemplated that these parameters may vary depending upon the application, substrate to be processed, and/or the size of the processing chamber.

In another exemplary embodiment where a SiGe epitaxial material is desired, the processing reagents may comprise a silicon source comprising dichlorosilane (DCS) and a germanium source comprising germanium tetrachloride (GeCl₄). For a 200 mm or 300 mm substrate, DCS may be provided into the process chamber at a flow rate ranging from about 300 sccm to about 800 sccm, such as about 450 sccm to about 650 sccm, for example about 500 sccm. GeCl₄ may be provided into the process chamber at a flow rate ranging from about 300 sccm to about 800 sccm, such as about 450 sccm to about 650 sccm, for example about 500 sccm. The carrier gas may have a flow rate from about 0.8 SLM (standard liters per minute) to about 27 SLM, such as from about 1.8 SLM to about 18 SLM. A dopant gas (if used) may be provided into the process chamber at a flow rate ranging from about 0.1 sccm to about 600 sccm, such as from about 0.5 sccm to about 150 sccm, for example, about 3 sccm to about 100 sccm. The total flow may be about 2 SLM (standard liters per minute) to about 30 SLM, for example about 5 SLM to about 20 SLM, for a 200 mm or 300 mm substrate. The epitaxial process may be a low temperature process (e.g., below 650° C.). In one exemplary example, the epitaxial process is performed at 800° C. or below, for example about 750° C. or below, such as about 500° C. to about 750° C., about 550° C. to about 650° C., for example about 600° C., and a chamber pressure of about 5 Torr to about 760 Torr, such as about 20 Torr to about 100 Torr, for example about 40 Torr.

At box 110, once the trenches 204 are filled with the epitaxial material 210, a planarization process may be performed to planarize portions of the epitaxial material 210 in the trenches 204 so that a top surface 212 of the epitaxial material 210 is substantially level with a top surface of the dielectric layer 202, as shown in FIG. 2D. In the embodiment as shown, the top surface 212 of the epitaxial material 210 is level with the top surface 214 of the silicon nitride 202b. The planarization process may include a chemical mechanical polish (CMP).

At box 112, a portion of the dielectric layer 202, i.e., the silicon nitride 202b, is selectively removed relative to the silicon oxide 202a and the epitaxial material 210 to form fins 214, as shown in FIG. 2E. The fins 214 may be employed in forming channels for FinFET transistor in later stages.

The concept described in embodiments of the present disclosure is also applicable to other epitaxial materials for trench filling. Some examples may include undoped silicon, Si:CP, pure Ge, GeSn, GeP, GeB, or GeSnB, etc., which may be used in logic and memory applications. In such cases, possible silicon precursors may comprise halogenated silicon compounds and optionally silicon-containing compounds as those described above, and possible germanium precursors may comprise halogenated germanium compounds and optionally germanium-containing compounds as those described above.

Benefits of the present disclosure include effective trench filling of high quality epitaxial SiGe material without losing selectivity of growth to dielectrics by using a silicon source comprising chlorinated silane and a germanium source comprising chlorinated germane. It has been observed that epitaxial SiGe fill can be performed in 20 nm to 30 nm wide trenches with excellent selectivity of growth to both silicon oxides and silicon nitrides appeared on the trench sidewall. Particularly, the trench filling of epitaxial material can optionally be performed without the use of typical co-flow etchant gases such as Cl₂ and HCl. The epitaxial growth using halogenated silane and halogenated germane for trench filling allows for better wetting on dielectric sidewalls, resulting in superior surface morphology of the epitaxial material in the trenches.

While the foregoing is directed to embodiments of the present disclosure, other and further embodiments of the disclosure may be devised without departing from the basic scope thereof, and the scope thereof is determined by the claims that follow.

We claim:

1. A method of processing a substrate, comprising:
epitaxially growing a silicon-containing material within a trench formed in a dielectric layer by exposing the trench to a gas mixture consisting of a deposition gas that includes silane (SiH₄) and a halogenated germanium compound at a temperature of about 500° C. to about 750° C., wherein the trench has a sidewall, and the sidewall comprises an oxide region and a nitride region.

2. The method of claim 1, wherein the halogenated germanium compound comprises a chlorinated germane.

3. The method of claim 2, wherein the deposition gas further comprises a carrier gas and/or a dopant gas.

4. The method of claim 1, wherein the halogenated germanium compound is a brominated germanium compound.

5. A method of processing a substrate, comprising:
forming a dielectric layer stack on a substrate, wherein the dielectric layer stack comprises an oxide layer and a nitride layer;
forming a trench through the dielectric layer to expose a surface of the substrate, wherein the trench has a sidewall containing the oxide region and the nitride region; and
epitaxially growing a silicon-containing material in the trench by exposing the sidewall to a gas mixture consisting of a deposition gas that includes a halogenated silicon compound and a halogenated germanium compound at a temperature about 750° C. or below.

6. The method of claim 5, wherein the deposition gas further comprises a carrier gas and/or a dopant gas.

7. The method of claim 5, wherein the wherein the halogenated silicon compound comprises a chlorinated silane.

8. The method of claim 7, wherein the halogenated germanium compound comprises a chlorinated germane.

9. The method of claim 8, wherein the chlorinated silane comprises silicon tetrachloride (SiCl₄), monochlorosilane (SiH₃Cl), dichlorosilane (SiH₂Cl₂), trichlorosilane (SiHCl₃), hexachlorodisilane (Si₂Cl₆), octachlorotrisilane (Si₃Cl₈), or a combination of two or more thereof, and wherein the chlorinated germane comprises germanium tetrachloride (GeCl₄), chlorogermane (GeH₃Cl), dichlorogermane (GeH₂Cl₂), trichlorogermane (GeHCl₃), hexachlorodigermane (Ge₂Cl₆), octachlorotrigermane (Ge₃Cl₈), or a combination of two or more thereof.

10. The method of claim 8, wherein the halogenated silicon compound is dichlorosilane (SiH₂Cl₂) and the halogenated germanium compound is germanium tetrachloride (GeCl₄).

11. The method of claim 10, wherein the silicon-containing material is epitaxially grown at a temperature of about 500° C. to about 750° C.

12. A method of processing a substrate, comprising:
forming a dielectric layer on a silicon substrate, wherein the dielectric layer comprises an oxide layer and a nitride layer;
exposing a portion of the silicon substrate through a trench formed in the dielectric layer, the trench having a sidewall containing the oxide region and the nitride region from the dielectric layer; and
exposing the sidewall to a gas mixture consisting of a deposition gas that includes a silicon compound and a germanium compound at a temperature about 500° C. to about 750° C.

13. The method of claim 12, wherein the silicon compound is silane (SiH₄).

14. The method of claim 12, wherein the silicon compound is a halogenated silicon compound.

15. The method of claim 14, wherein the silicon compound is a brominated silicon compound

16. The method of claim 14, wherein the silicon compound is a chlorinated silane.

17. The method of claim 16, wherein the deposition gas further comprises a carrier gas and/or a dopant gas.

18. The method of claim 15, wherein the germanium compound is a brominated germanium compound.

19. The method of claim 16, wherein the germanium compound is a chlorinated germane.

20. The method of claim 19, wherein the chlorinated silane comprises silicon tetrachloride (SiCl₄), monochlorosilane (SiH₃Cl), dichlorosilane (SiH₂Cl₂), trichlorosilane (SiHCl₃), hexachlorodisilane (Si₂Cl₆), octachlorotrisilane (Si₃Cl₈), or a combination of two or more thereof, and wherein the chlorinated germane comprises germanium tetrachloride (GeCl₄), chlorogermane (GeH₃Cl), dichlorogermane (GeH₂Cl₂), trichlorogermane (GeHCl₃), hexachlorodigermane (Ge₂Cl₆), octachlorotrigermane (Ge₃Cl₈), or a combination of two or more thereof.
